(19) United States
(12) Patent Application Publication
(10) Pub. No.: US 2026/0343900 A1
(43) Pub. Date: Oct. 29, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Nam Kyun PARK, Icheon-si (KR); Jae Gil LEE, Icheon-si (KR)

(21) Appl. No.: 19/364,769

(22) Filed: Oct. 21, 2025

(30) Foreign Application Priority Data
Apr. 23, 2025 (KR) 10-2025-0053052

(51) Int. Cl. H10B 63/00; G11C 5/06; H10B 61/00; H10D 30/01; H10D 30/63; H10D 64/27

(52) U.S. Cl. CPC H10B 63/34; G11C 5/063; H10B 63/845; H10D 30/63; H10D 64/516; H10D 64/518; H10B 61/10; H10D 30/025

(57) ABSTRACT

A semiconductor device includes: channel pillars arranged in a first direction and a second direction and each including a first end portion, a second end portion, and a channel portion; first gap-fill insulating layers disposed between the channel pillars adjacent to each other in the first direction; first gate insulating layers disposed between the channel pillars and the first gap-fill insulating layers so as to surround the second end portion; second gap-fill insulating layers disposed between the channel pillars adjacent to each other in the second direction; second gate insulating layers disposed between the channel pillars and the second gap-fill insulating layers so as to cover the second end portion; select lines surrounding sidewalls of the channel pillars arranged in the first direction; and third gate insulating layers each surrounding the channel portions and overlapping with the first and second gate insulating layers.

### CROSS-REFERENCE TO RELATED APPLICATION

[symbol] his application claims priority under 35 U.S.C. § 119 to Korean Patent Application No. 10-2025-0053052 filed on Apr. 23, 2025, which is incorporated herein by reference in its entirety.

### BACKGROUND

### 1. Technical Field

[symbol] mbodiments of the present disclosure relate to an electronic device, and more particularly, to a semiconductor device and a method of manufacturing the semiconductor device.

### 2. Related Art

[symbol] he degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

[symbol] n an embodiment, a semiconductor device may include: channel pillars arranged in a first direction and a second direction intersecting the first direction, each of the channel pillars including a first end portion, a second end portion, and a channel portion disposed between the first portion end and the second end portion; first gap-fill insulating layers each disposed between a first pair of the channel pillars adjacent to each other in the first direction; first gate insulating layers each disposed between a corresponding one of the channel pillars and a corresponding one of the first gap-fill insulating layers so as to cover the second end portion; second gap-fill insulating layers each disposed between a second pair of the channel pillars adjacent to each other in the second direction and extending in the first direction; second gate insulating layers each disposed between the corresponding one of the channel pillars and a corresponding one of the second gap-fill insulating layers so as to cover the second end portion; select lines each surrounding sidewalls of a first plurality of the channel pillars arranged in the first direction and extending in the first direction; and third gate insulating layers each surrounding the channel portions of the first plurality of the channel pillars and overlapping with corresponding ones of the first and second gate insulating layers.

[symbol] n an embodiment, a semiconductor device may include: channel pillars arranged in a first direction and a second direction intersecting the first direction, each of the channel pillars including a first end portion, a second end portion, and a channel portion disposed between the first end portion and the second end portion; fourth gate insulating layers covering respective sidewalls of the first end portion that face each other in the first direction; fifth gate insulating layers covering respective sidewalls of the first end portion that face each other in the second direction; select lines each extending in the first direction and surrounding sidewalls of a first plurality of the channel pillars arranged in the first direction; and third gate insulating layers each surrounding the channel portions of the first plurality of the channel pillars and overlapping with corresponding ones of the fourth and fifth gate insulating layers.

[symbol] n an embodiment, a method of manufacturing a semiconductor device may include: forming a channel layer; forming channel patterns and first trenches by etching the channel layer, the channel patterns extending in a second direction, the first trenches each being formed between a pair of the channel patterns adjacent in a first direction intersecting the second direction; forming an initial first gate insulating layer in the first trenches; forming first gap-fill insulating layers on the initial first gate insulating layer; forming channel pillars, second trenches, and intermediate first gate insulating layers by etching the channel patterns, the first gap-fill insulating layers, and the initial first gate insulating layer, the channel pillars being arranged in the first direction and the second direction, the second trenches extending in the first direction; forming an initial second gate insulating layer in the second trenches; forming second gap-fill insulating layers on the initial second gate insulating layer; forming a third trench, first gate insulating layers, and second gate insulating layers by etching the second gap-fill insulating layers, the initial second gate insulating layer, the first gap-fill insulating layers, and the intermediate first gate insulating layers, the third trench exposing sidewalls of the channel pillars; forming an initial third gate insulating layer in the third trench, the initial third gate insulating layer surrounding the sidewalls of the channel pillars; forming select lines extending in the first direction and each surrounding a first plurality of the channel pillars arranged in the first direction with corresponding ones of the first, second, and third gate insulating layers interposed therebetween, and forming third gate insulating layers by etching the initial third gate insulating layer.

[symbol] n an embodiment, a method of manufacturing a semiconductor device may include: forming a channel layer; forming first preliminary trenches by etching the channel layer, the first preliminary trenches extending in a second direction; forming a fourth gate insulating layer in the first preliminary trenches; forming channel patterns and first trenches by etching the fourth gate insulating layer and the channel layer, the channel patterns extending in the second direction, and the first trenches being disposed between the channel patterns; forming a first gate insulating layer and first gap-fill insulating layers in the first trenches; forming channel pillars and second trenches by etching the channel patterns, the first gate insulating layer, the first gap-fill insulating layers, and the fourth gate insulating layer, the channel pillars being arranged in the second direction and a first direction intersecting the second direction, and the second trenches extending in the first direction; forming a second gate insulating layer and second gap-fill insulating layers in the second trenches; forming a third trench by etching the second gate insulating layer, the second gap-fill insulating layers, the first gate insulating layer, and the first gap-fill insulating layers, the third trench exposing sidewalls of the channel pillars; forming a third gate insulating layer in the third trench, the third gate insulating layer overlapping with the fourth gate insulating layer; and forming select lines extending in the first direction and surrounding the channel pillars arranged in the first direction with the first to fourth gate insulating layers interposed therebetween.

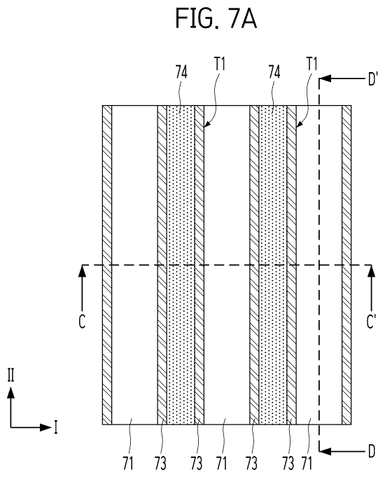

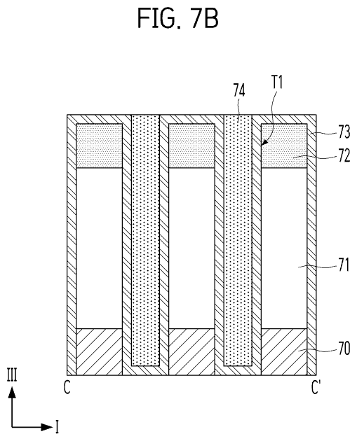

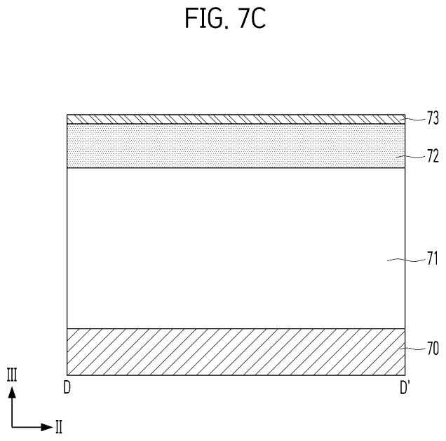

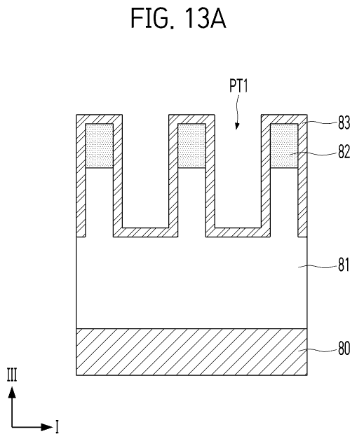

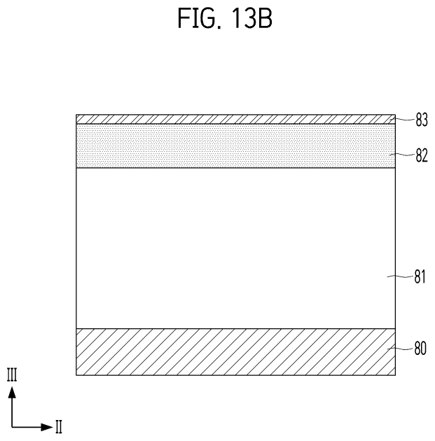

### BRIEF DESCRIPTION OF THE DRAWINGS

[symbol] IG. 1 is a diagram illustrating the structure of a semiconductor device in accordance with an embodiment.

[symbol] IG. 2 is a circuit diagram illustrating the configuration of a semiconductor device in accordance with an embodiment.

[symbol] IGS. 3A to 3C are diagrams illustrating the structure of a semiconductor device in accordance with an embodiment.

[symbol] IGS. 4A and 4B are diagrams illustrating the structure of a semiconductor device in accordance with an embodiment.

[symbol] IGS. 5A and 5B are diagrams illustrating the structure of a semiconductor device in accordance with an embodiment.

[symbol] IG. 6 is a diagram illustrating the structure of a semiconductor device in accordance with an embodiment.

[symbol] IGS. 7A, 8A, 9A, 10A, 11A, and 12A, FIGS. 7B, 8B, 9B, 10B, 11B, and 12B, and FIGS. 7C, 8C, 9C, 10C, 11C, and 12C are diagrams for describing a method of manufacturing a semiconductor device in accordance with an embodiment.

[symbol] IGS. 13A, 14A, 15A, 16A, 17A, an 18A and FIGS. 13B, 14B, 15B, 16B, 17B, and 18B are diagrams for describing a method of manufacturing a semiconductor device in accordance with an embodiment.

[symbol] IGS. 19A, 19B, 20A, and 20B are diagrams for describing a method of manufacturing a semiconductor device in accordance with an embodiment.

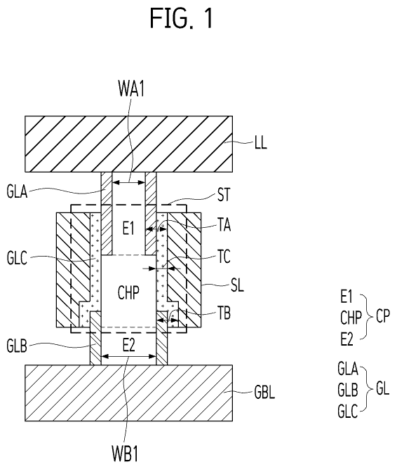

### DETAILED DESCRIPTION

[symbol] arious embodiments are directed to a semiconductor device having a stable structure and improved characteristics and a method of manufacturing the semiconductor device.

[symbol] y stacking memory cells in three dimensions, it is possible to improve the degree of integration of a semiconductor device. It is also possible to provide a semiconductor device having a stable structure and improved reliability.

[symbol] ereafter, some embodiments of the present disclosure will be described with reference to the accompanying drawings.

[symbol] IG. 1 is a diagram illustrating the structure of a semiconductor device in accordance with an embodiment.

[symbol] eferring to FIG. 1, the semiconductor device may include a global line GBL, a local line LL, and a select transistor ST. The select transistor ST may be connected between the global line GBL and the local line LL, and may control the connection between the global line GBL and the local line LL. When the select transistor ST is turned on, the global line GBL and the local line LL are electrically connected to each other, and when the select transistor ST is turned off, the global line GBL and the local line LL are electrically disconnected from each other. As an example, the global line GBL may be a global bit line, and the local line LL may be a local bit line.

[symbol] he select transistor ST may include a channel pillar CP. The select transistor ST may be disposed in a region where the channel pillar CP and a select line SL intersect each other. The channel pillar CP may include a first end portion E1, a second end portion E2, and a channel portion CHP disposed between the first end portion E1 and the second end portion E2. The first end portion E1 and the second end portion E2 may be junctions such as a source region and/or a drain region. The first end portion E1 may be connected to the local line LL, and the second end portion E2 may be connected to the global line GBL. The first end portion E1 may have a first width WA1, and the second end portion E2 may have a second width WB1, and the first width WA1 may be smaller than the second width WB1.

[symbol] he select transistor ST may include a gate insulating layer GL. The gate insulating layer GL may include a first gate insulating layer GLA, a second gate insulating layer GLB, and a third gate insulating layer GLC. The first gate insulating layer GLA may surround the first end portion E1, the second gate insulating layer GLB may surround the second end portion E2, and the third gate insulating layer GLC may surround the channel portion CHP. A sidewall of the first gate insulating layer GLA may be substantially aligned with a sidewall of the second end portion E2.

[symbol] he third gate insulating layer GLC may overlap with the first gate insulating layer GLA, overlap with the second gate insulating layer GLB, or overlap with the first and second gate insulating layers GLA and GLB. As an example, the third gate insulating layer GLC may surround the sidewall of the first gate insulating layer GLA. The third gate insulating layer GLC may surround an upper surface and a sidewall of the second gate insulating layer GLB.

[symbol] he select line SL may surround a sidewall of the channel pillar CP with the first to third gate insulating layers GLA to GLC interposed therebetween. An upper surface of the third gate insulating layer GLC may be disposed at a lower level than an upper surface of the channel pillar CP, and may be disposed at substantially the same level as an upper surface of the select line SL.

[symbol] he gate insulating layer GL may have a first thickness TA between the first end portion E1 and the select line SL, have a second thickness TB between the second end portion E2 and the select line SL, and have a third thickness TC between the channel portion CHP and the select line SL. At least one of the first thickness TA and the second thickness TB may be greater than the third thickness TC.

[symbol] ccording to the structure described over, a thickness of the gate insulating layer GL of the select transistor ST may be locally increased.

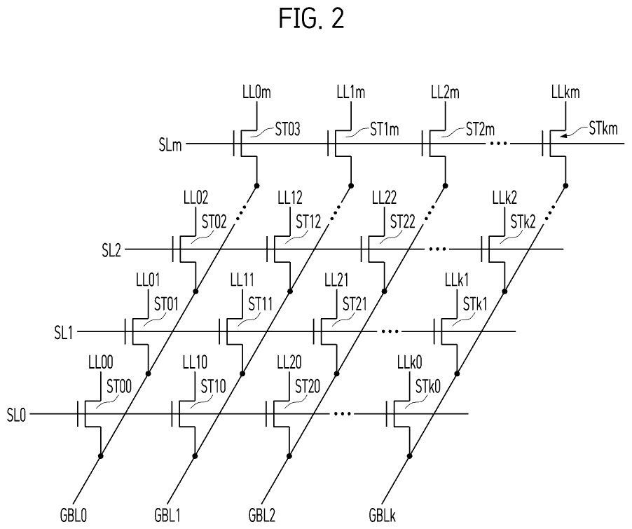

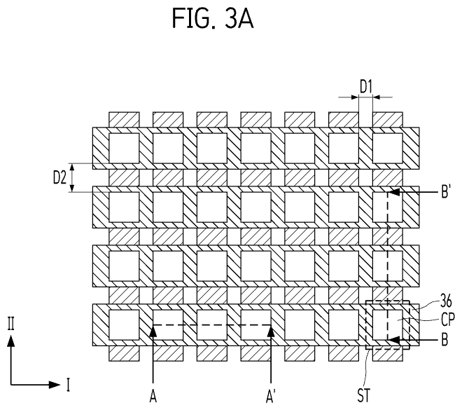

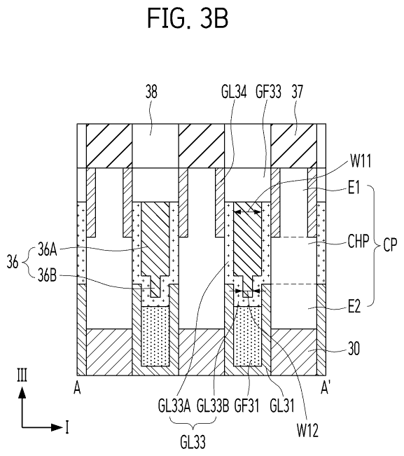

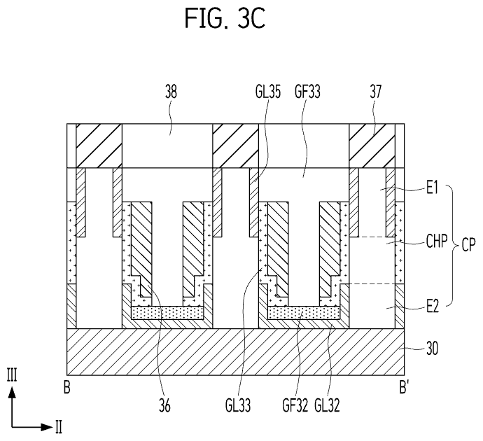

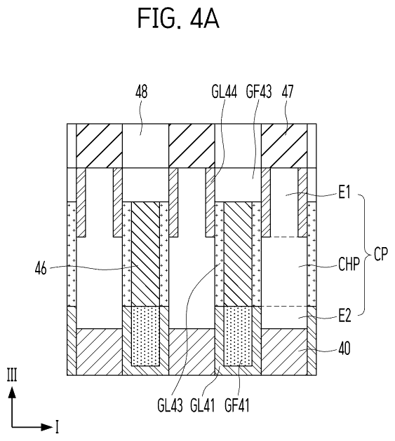

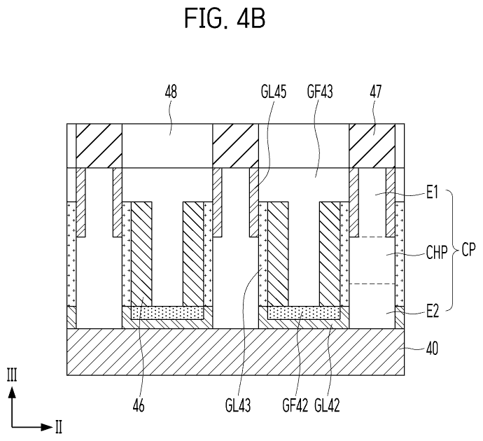

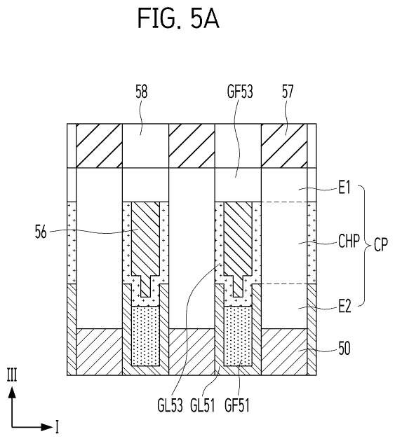

Accordingly, an occurrence of gate induced drain leakage (GIDL) during an operation of the select transistor ST may be reduced.

[symbol] IG. 2 is a circuit diagram illustrating the configuration of a semiconductor device in accordance with an embodiment. Hereinafter, the content overlapping with the previously described content may be omitted for the interest of brevity.

[symbol] eferring to FIG. 2, the semiconductor device may include a plurality of global lines GBL0 to GBLk, a plurality of local lines LLO0 to LLkm, a plurality of select transistors ST00 to STkm, and a plurality of select lines SL0 to SLm. The select transistors ST00 to STkm may be arranged in a matrix form, and may be connected between the global lines GBL0 to GBLk and the local lines LL00 to LLkm, respectively. As an example, the select transistors ST00 to STkm may operate in both directions, and a current may flow in both directions of channel pillars CP.

[symbol] ccording to such a circuit configuration, GIDL may occur in a process of turning on the selected select transistor ST11. An operating voltage is applied to the selected global line GBL1, and a ground voltage is applied to the unselected global lines GBL0 and GBL2 to GBLk. A turn-on voltage is applied to the selected select line SL1, and a turn-off voltage is applied to the unselected select lines SL0 and SL2 to SLm. In such a case, GIDL may occur in the unselected transistors ST10 and ST12 to ST1m connected to the selected global line GBL1.

[symbol] ccordingly, according to an embodiment of the present disclosure, by locally increasing thicknesses of gate insulating layers GL of the select transistors ST00 to STkm, it is possible to reduce the occurrence of the GIDL. Referring to FIG. 1 again, the select transistor ST may operate in both directions, and the first end portion E1 or the second end portion E2 may act as a drain region depending on an operation direction of the select transistor ST. By overlapping the first gate insulating layer GLA and the third gate insulating layer GLC with each other or by overlapping the second gate insulating layer GLB and the third gate insulating layer GLC with each other, it is possible to increase the thickness of the gate insulating layer GL in the drain region.

[symbol] hen the thickness of the gate insulating layer GL is relatively small, a magnitude of an electric field applied to the channel pillar CP may increase, and multiple electron-hole pairs may be generated to cause the GIDL. In contrast, when the thickness of the gate insulating layer GL is relatively great, a magnitude of an electric field applied to the gate insulating layer GL may increase, and a magnitude of an electric field applied to the channel pillar CP may decrease. In such a case, the occurrence of electron-hole pairs is reduced, and the GIDL is also reduced. Accordingly, by increasing the thickness of the gate insulating layer GL at the first end E1 and the second end E2, it is possible to reduce the occurrence of the GIDL.

[symbol] or reference, it is also possible to increase the thickness of the gate insulating layer GL only at the first end portion E1 or increase the thickness of the gate insulating layer GL only at the second end portion E2. As an example, when the select transistor ST operates in a single direction, the thickness of the gate insulating layer GL at an end corresponding to the drain region may be increased.

[symbol] IGS. 3A to 3C are diagrams illustrating the structure of a semiconductor device in accordance with an embodiment. FIG. 3A is a plan view, FIG. 3B is a cross-sectional view taken along line A-A′ of FIG. 3A, and FIG. 3C is a cross-sectional view taken along line B-B′ of FIG. 3A. Hereinafter, the content overlapping with the previously described content may be omitted for the interest of brevity.

[symbol] eferring to FIGS. 3A to 3C, the semiconductor device may include channel pillars CP, first gate insulating layers GL31, second gate insulating layers GL32, third gate insulating layers GL33, first gap-fill insulating layers GF31, second gap-fill insulating layers GF32, and select lines 36. The semiconductor device may further include fourth gate insulating layers GL34, fifth gate insulating layers GL35, third gap-fill insulating layers GF33, an insulating layer 38, global lines 30, and local lines 37.

[symbol] he channel pillars CP may be arranged in a first direction I and a second direction II intersecting the first direction I. Each of the channel pillars CP may have a pillar shape in which it extends in a third direction III. The third direction III may be a direction perpendicular to the first direction I and the second direction II. In a cross-section defined by the first direction I and the second direction II, the channel pillar CP may have a shape such as a circular shape, an elliptical shape, or a polygonal shape. As an example, the channel pillar CP may have a cross-section with a rectangular shape. Each of the channel pillars CP may include a first end portion E1, a second end portion E2, and a channel portion CHP. The first end portion E1 may have a smaller width than the second end portion E2.

[symbol] first pair of the channel pillars CP adjacent to each other in the first direction I may be spaced apart from each other by a first distance D1, and a second pair of the channel pillars CP adjacent to each other in the second direction II may be spaced apart from each other by a second distance D2. The first distance D1 may be smaller than the second distance D2.

[symbol] he global lines (e.g., global bit lines) 30 may be disposed under the channel pillars CP. The global lines 30 may extend in the second direction II, and each of the global lines 30 may be connected to a plurality of the channel pillars CP arranged in the second direction II. The global line 30 may be connected to the second end portion E2.

[symbol] he first gap-fill insulating layers GF31 may be disposed between the channel pillars CP adjacent to each other in the first direction I and between the global lines 30 adjacent to each other in the first direction I. For example, the first gap-fill insulating layers GF31 may each be disposed between a first pair of the channel pillars CP adjacent to each other in the first direction I and between a pair of the global lines 30 adjacent to each other in the first direction I. The first gate insulating layers GL31 may be disposed between the channel pillars CP and the first gap-fill insulating layers GF31 so as to cover the second end portion E2. For example, the first gate insulating layers GL31 may each be disposed between a corresponding (e.g., contacting) one of the channel pillars CP and a corresponding (e.g., contacting) one of the first gap-fill insulating layers GF31 so as to cover the second end portion E2 of the corresponding channel pillar CP. The first gate insulating layers GL31 may cover sidewalls of the second end portions E2 that face each other in the first direction I. The first gate insulating layers GL31 may extend between the global lines 30 and the first gap-fill insulating layers GF31, and may surround lower surfaces of the first gap-fill insulating layers GF31.

[symbol] he first gate insulating layers GL31 may each include an insulating material such as oxide or nitride. As an example, the first gate insulating layers GL31 may each include SiOₓ, AlOₓ, TiOₓ, HfOₓ, LaOₓ, ZrOₓ, IGZO, ITO, IZO, InOₓ, SiN, or the like.

[symbol] he second gap-fill insulating layers GF32 may be disposed between the channel pillars CP adjacent to each other in the second direction II, and may extend in the first direction I. For example, the second gap-fill insulating layers GF32 may each be disposed between a second pair of the channel pillars CP adjacent to each other in the second direction II, and may extend in the first direction I. The second gate insulating layers GL32 may be disposed between the channel pillars CP and the second gap-fill insulating layers GF32 so as to cover the second end portion E2. For example, the second gate insulating layers GL32 may each be disposed between a corresponding (e.g., contacting) one of the channel pillars CP and a corresponding (e.g., contacting) one of the second gap-fill insulating layers GF32 so as to cover the second end portion E2 of the corresponding channel pillar CP. The second gate insulating layers GL32 may cover sidewalls of the second end portions E2 that face each other in the second direction II. The second gate insulating layers GL32 may extend between the global lines 30 and the second gap-fill insulating layers GF32, and may surround lower surfaces of the second gap-fill insulating layers GF32.

[symbol] he second gate insulating layers GL32 may each include an insulating material such as oxide or nitride. As an example, the second gate insulating layers GL32 may each include SiOₓ, AlOₓ, TiOₓ, HfOₓ, LaOₓ, ZrOₓ, IGZO, ITO, IZO, InOₓ, SIN, or the like.

[symbol] he select lines 36 may surround sidewalls of the channel pillars CP arranged in the first direction I, and may extend in the first direction I. For example, the select lines 36 may each surround sidewalls of a plurality of the channel pillars CP arranged in the first direction I, and may each extend in the first direction I. The third gate insulating layers GL33 may be disposed between the channel pillars CP and the select lines 36 so as to surround the channel portion CHP. The third gate insulating layers GL3 may overlap with the first and second gate insulating layers GL31 and GL32. For example, the third gate insulating layers GL33 may each surround the channel portions CHP of the plurality of the channel pillars CP arranged in the first direction I and overlapping with corresponding (e.g., contacting) ones of the first and second gate insulating layers GL31 and GL32. The third gate insulating layers GL33 may each include an insulating material such as oxide or nitride. As an example, the third gate insulating layers GL33 may each include SiOₓ, AlOₓ, TiOₓ, HfOₓ, LaOₓ, ZrOₓ, IGZO, ITO, IZO, InOₓ, SIN, or the like.

[symbol] he select lines 36 may surround the sidewalls of the channel pillars CP arranged in the first direction I with the first to third gate insulating layers GL31 to GL33 interposed therebetween. For example, the select lines 36 may each surround sidewalls of the plurality of the channel pillars CP arranged in the first direction I with corresponding (e.g., contacting or adjacent) ones of the first, second, and third gate insulating layers GL31, GL32, and GL33 interposed therebetween. The select lines 36 may each include a conductive material such as metal or metal nitride. As an example, the select lines 36 may each include TIN, W, WSIN, WN, or the like.

[symbol] pper surfaces of the first gap-fill insulating layers GF31 may be disposed at a lower level than upper surfaces of the first gate insulating layers GL31. Upper surfaces of the second gap-fill insulating layers GF32 may be disposed at a lower level than upper surfaces of the second gate insulating layers GL32. The third gate insulating layers GL33 may extend along surfaces of the first gate insulating layers GL31, the first gap-fill insulating layers GF31, the second gate insulating layers GL32, and the second gap-fill insulating layers GF32.

[symbol] ach of the third gate insulating layers GL33 may include a first portion GL33A surrounding the channel portion CHP of a corresponding (e.g., contacting) one of the channel pillars CP and a second portion GL33B covering a corresponding (e.g., contacting) one of the first gate insulating layers GL31 and a corresponding one of the second gate insulating layers GL32. A portion 36A of the select line 36 corresponding to the first portion GL33A may have a first width W11, and a portion 36B of the select line 36 corresponding to the second portion GL33B may have a second width W12 smaller than the first width W11. For example, each of the select lines 36 may have a first portion 36A that is covered by the first portion GL33A of a corresponding (e.g., contacting) one of the third gate insulating layers GL33 and has a first width W11. In addition, each of the select lines 36 may have a second portion 36B that is covered by the second portion GL33B of the corresponding one of the third gate insulating layers GL33 and has a second width W12 smaller than the first width W11.

[symbol] he third gap-fill insulating layer GF33 may be disposed between the channel pillars CP adjacent to each other in the first direction I and between the channel pillars CP adjacent to each other in the second direction II so as to surround the first end portion E1. For example, the third gap-fill insulating layer GF33 may be disposed between a first plurality of the channel pillars CP adjacent to each other in the first direction I and between a second plurality of the channel pillars CP adjacent to each other in the second direction II so as to surround the first end portion E1 of a corresponding (e.g., adjacent) one of the channel pillars CP. The third gap-fill insulating layer GF33 may extend between the select lines (e.g., a pair of the select lines) 36 adjacent to each other in the second direction II.

[symbol] he fourth gate insulating layers GL34 may cover sidewalls facing each other in the first direction I at the first end portion E1. For example, the fourth gate insulating layers GL34 may cover respective sidewalls of the first end portion E1 that face each other in the first direction I. The fourth gate insulating layers GL34 may be disposed between the channel pillars CP and the third gap-fill insulating layers GF33, and may overlap with the third gate insulating layers GL33. For example, the fourth gate insulating layers GL34 may each be disposed between a corresponding (e.g., contacting) one of the channel pillars CP and a corresponding (e.g., contacting) one of the third gap-fill insulating layers GF33, and may overlap with a corresponding (e.g., contacting) one of the third gate insulating layers GL33. The fourth gate insulating layers GL34 may each include an insulating material such as oxide or nitride. As an example, the fourth gate insulating layers GL34 may each include SiOₓ, AlOₓ, TiOₓ, HfOₓ, LaOₓ, ZrOₓ, IGZO, ITO, IZO, InOₓ, SiN, or the like.

[symbol] he fifth gate insulating layers GL35 may cover sidewalls facing each other in the second direction II at the first end portion E1. For example, the fifth gate insulating layers GL35 may cover respective sidewalls of the first end portion E1 that face each other in the second direction II. The fifth gate insulating layers GL35 may be disposed between the channel pillars CP and the third gap-fill insulating layers GF33, and may overlap with the third gate insulating layers GL33. For example, the fifth gate insulating layers GL35 may each be disposed between a corresponding (e.g., contacting) one of the channel pillars CP and a corresponding (e.g., contacting) one of the third gap-fill insulating layers GF33, and may overlap with a corresponding (e.g., contacting) one of the third gate insulating layers GL33. The fifth gate insulating layers GL35 may each include an insulating material such as oxide or nitride. As an example, the fifth gate insulating layers GL35 may each include SiOₓ, AlOₓ, TiOₓ, HfOₓ, LaOₓ, ZrOₓ, IGZO, ITO, IZO, InOₓ, SIN, or the like.

[symbol] he local lines (e.g., local bit lines) 37 may be connected to the channel pillars CP, respectively. For reference, reference numeral “37” may denote a portion of the local line or may be a contact plug for connecting the local line and the channel pillar CP to each other. The local line 37 may be connected to the first end portion E1 of the channel pillar CP, and the global line 30 may be connected to the second end portion E2 of the channel pillar CP. The insulating layer 38 may be filled between the local lines 37.

[symbol] ccording to the structure described above, by overlapping the first and second gate insulating layers GL31 and GL32 with the third gate insulating layer GL33, and overlapping the fourth and fifth gate insulating layers GL34 and GL35 with the third gate insulating layer GL33, it is possible to locally increase a thickness of a gate insulating layer. Specifically, such a gate insulating layer including the first, second, third, fourth, and fifth gate insulating layers GL31, GL32, GL33, GL34, and GL35 may have an increased thickness in a region overlapping a drain region of the select transistor ST. Accordingly, the occurrence of GIDL during an operation of a select transistor ST may be reduced.

[symbol] IGS. 4A and 4B are diagrams illustrating the structure of a semiconductor device in accordance with an embodiment. Hereinafter, the content overlapping with the previously described content may be omitted for the interest of brevity.

[symbol] eferring to FIGS. 4A and 4B, the semiconductor device may include channel pillars CP, third gate insulating layers GL43, fourth gate insulating layers GL44, fifth gate insulating layers GL45, and select lines 46. The semiconductor device may further include first gate insulating layers GL41, second gate insulating layers GL42, first gap-fill insulating layers GF41, second gap-fill insulating layers GF42, third gap-fill insulating layers GF43, global lines 40, local lines 47, and an insulating layer 48.

[symbol] he channel pillars CP may be arranged in the first direction I and the second direction II intersecting the first direction I. Each of the channel pillars CP may include a first end portion E1, a second end portion E2, and a channel portion CHP. The global lines 40 may be disposed under the channel pillars CP. The global lines 40 may extend in the second direction II, and may each be connected to a plurality of the channel pillars CP arranged in the second direction II.

[symbol] he first gap-fill insulating layers GF41 may be disposed between the channel pillars CP adjacent to each other in the first direction I and between the global lines 40 adjacent to each other in the first direction I. For example, the first gap-fill insulating layers GF41 may each be disposed between a first pair of the channel pillars CP adjacent to each other in the first direction I and between a pair of the global lines 40 adjacent to each other in the first direction I. The first gate insulating layers GL41 may be disposed between the channel pillars CP and the first gap-fill insulating layers GF41 so as to cover the second end portion E2. For example, the first gate insulating layers GL41 may each be disposed between a corresponding (e.g., contacting) one of the channel pillars CP and a corresponding (e.g., contacting) one of the first gap-fill insulating layers GF41 so as to cover the second end portion E2 of the corresponding channel pillar CP. Upper surfaces of the first gap-fill insulating layers GF41 may be disposed at substantially the same level as upper surfaces of the first gate insulating layers GL41. For example, a difference between levels of the upper surface of the first gap-fill insulating layer GF41 and the upper surface of the first gate insulating layer GL41 may be equal to or smaller than 5%, 3%, or 1% of an average of the heights of the first gap-fill insulating layer GF41 and the first gate insulating layer GL41 in the third direction III.

[symbol] he second gap-fill insulating layers GF42 may be disposed between the channel pillars CP adjacent to each other in the second direction II, and may extend in the first direction I. For example, the second gap-fill insulating layers GF42 may each be disposed between a second pair of the channel pillars CP adjacent to each other in the second direction II, and may extend in the first direction I. The second gate insulating layers GL42 may be disposed between the channel pillars CP and the second gap-fill insulating layers GF42 so as to cover the second end portion E2. For example, the second gate insulating layers GL42 may each be disposed between a corresponding (e.g., contacting) one of the channel pillars CP and a corresponding (e.g., contacting) one of the second gap-fill insulating layers GF42 so as to cover the second end portion E2 of the corresponding channel pillar CP. Upper surfaces of the second gap-fill insulating layers GF42 may be disposed at substantially the same level as upper surfaces of the second gate insulating layers GL42.

[symbol] he fourth gate insulating layers GL44 may cover sidewalls facing each other in the first direction I at the first end E1. For example, the fourth gate insulating layers GL44 may cover respective sidewalls of the first end portion E1 that face each other in the first direction I. The fourth gate insulating layers GL44 may be disposed between the channel pillars CP and the third gap-fill insulating layers GF43, and may overlap with the third gate insulating layers GL43. For example, the fourth gate insulating layers GL44 may each be disposed between a corresponding (e.g., contacting) one of the channel pillars CP and a corresponding (e.g., contacting) one of the third gap-fill insulating layers GF43, and may overlap with a corresponding (e.g., contacting) one of the third gate insulating layers GL43.

[symbol] he fifth gate insulating layers GL45 may cover sidewalls facing each other in the second direction II at the first end portion E1. For example, the fifth gate insulating layers GL45 may cover respective sidewalls of the first end portion E1 that face each other in the second direction II. The fifth gate insulating layers GL45 may be disposed between the channel pillars CP and the third gap-fill insulating layers GF43, and may overlap with the third gate insulating layers GL43. For example, the fifth gate insulating layers GL45 may each be disposed between a corresponding (e.g., contacting) one of the channel pillars CP and a corresponding (e.g., contacting) one of the third gap-fill insulating layers GF43, and may overlap with a corresponding (e.g., contacting) one of the third gate insulating layers GL43.

[symbol] he select lines 46 may surround sidewalls of the channel pillars CP arranged in the first direction I, and may extend in the first direction I.

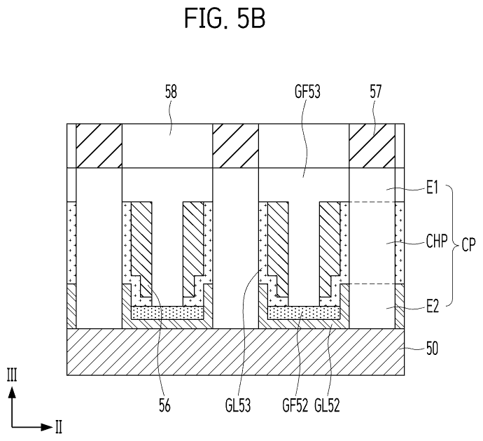

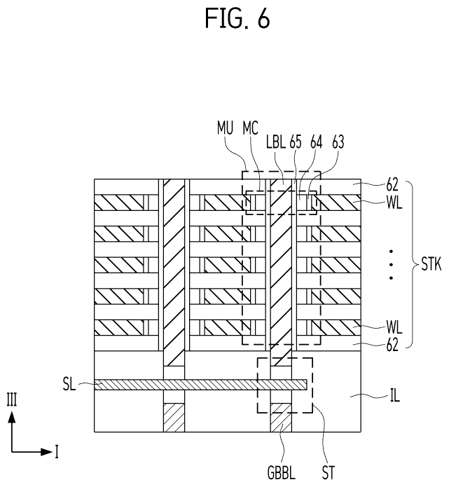

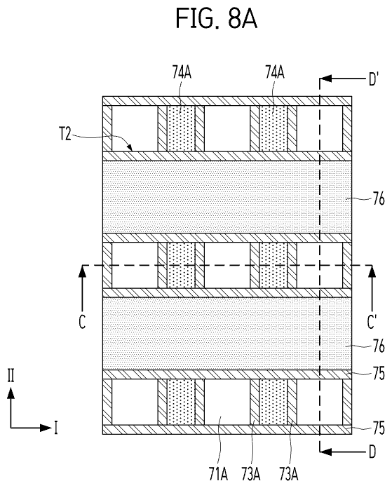

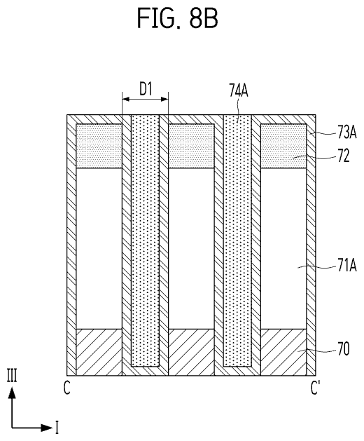

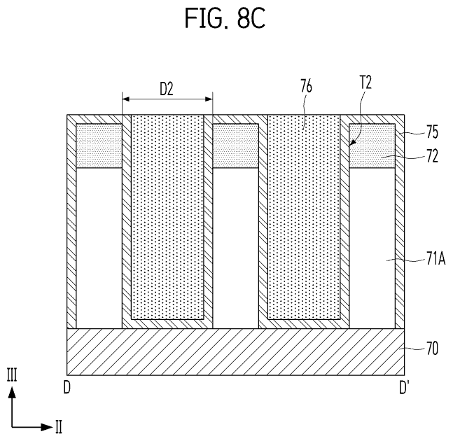

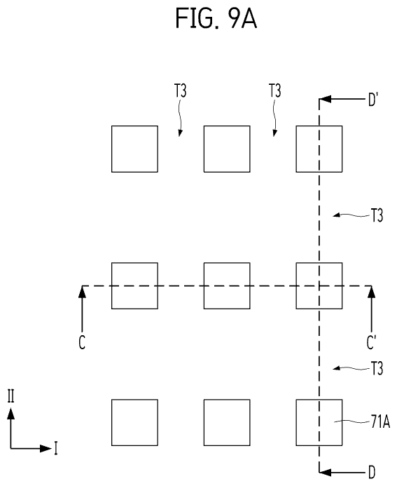

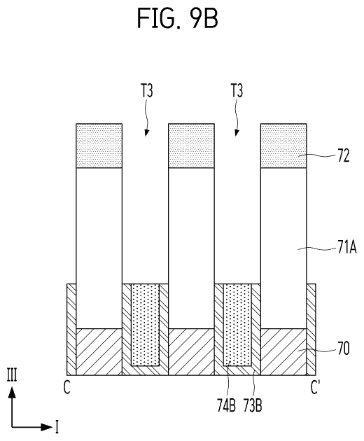

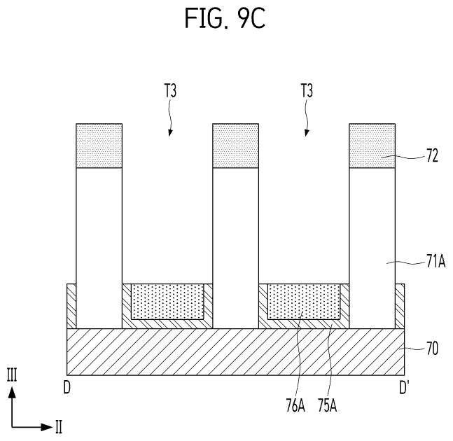

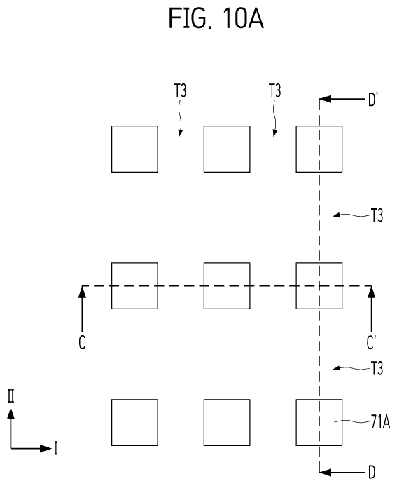

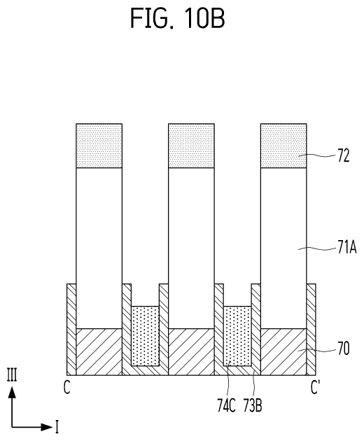

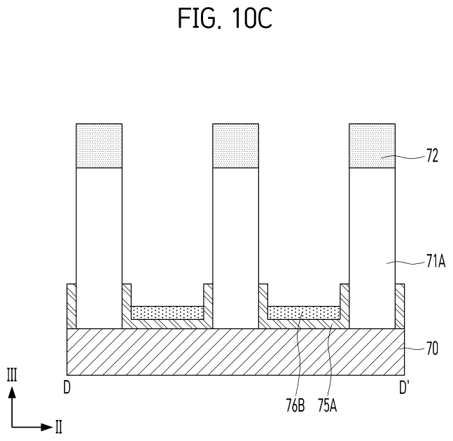

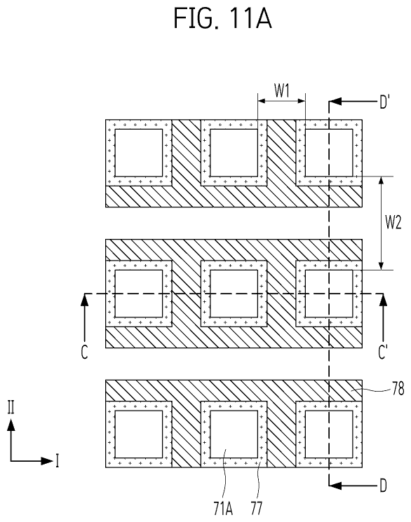

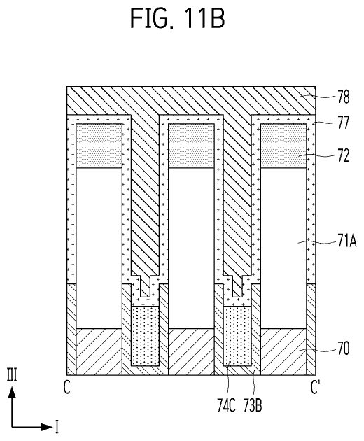

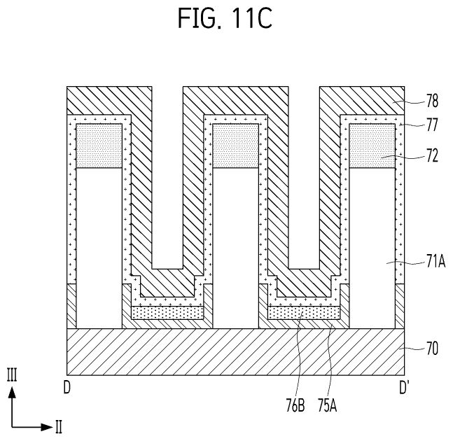

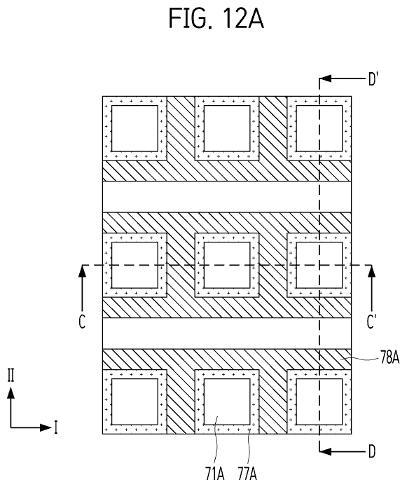

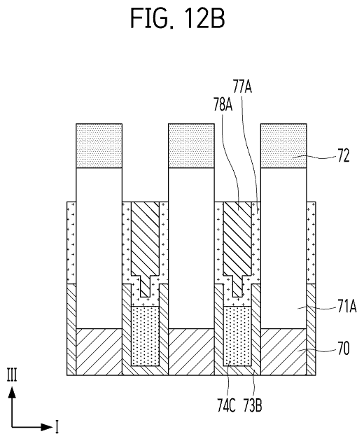

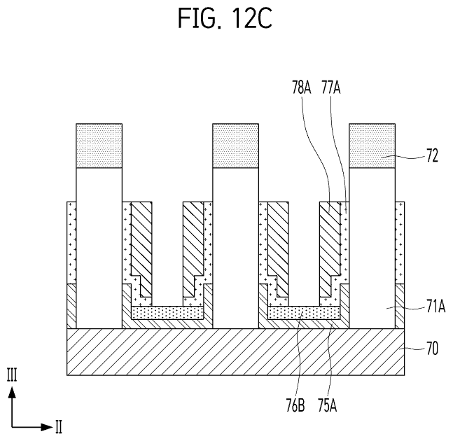

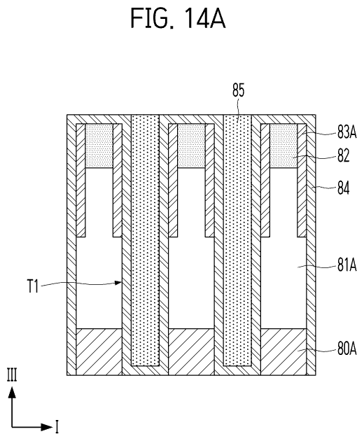

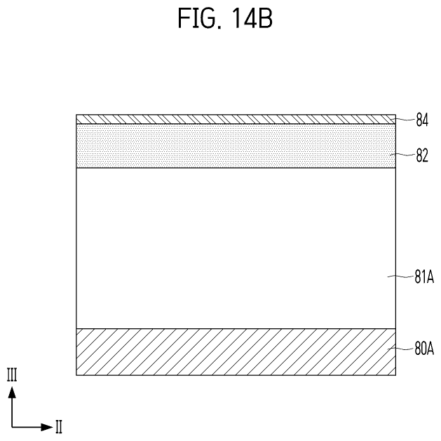

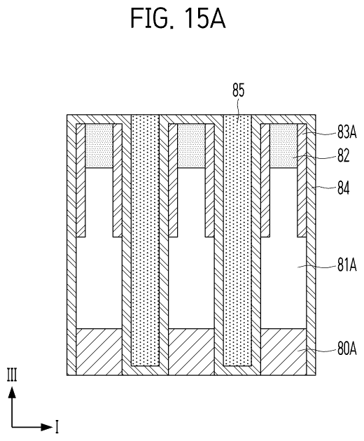

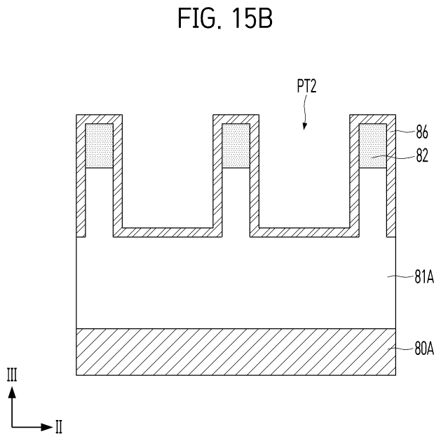

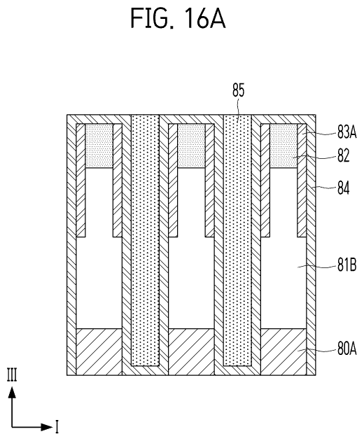

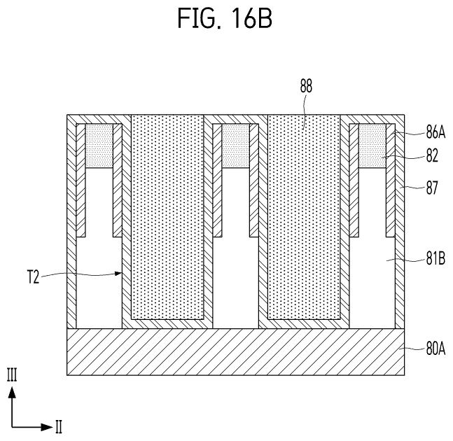

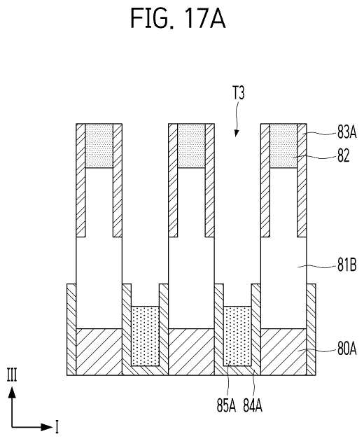

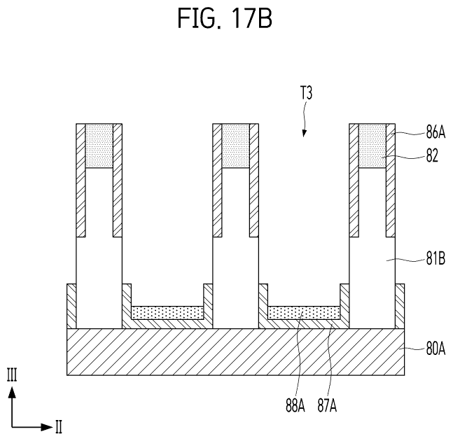

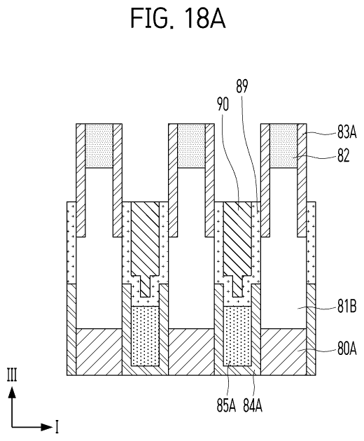

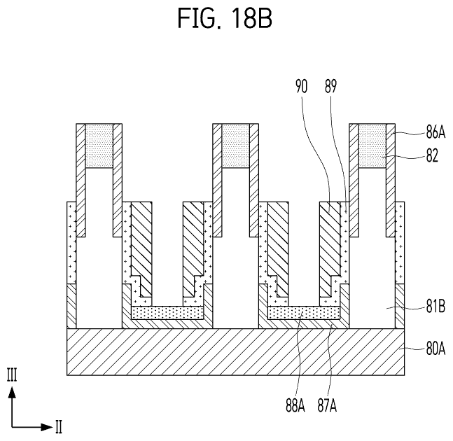

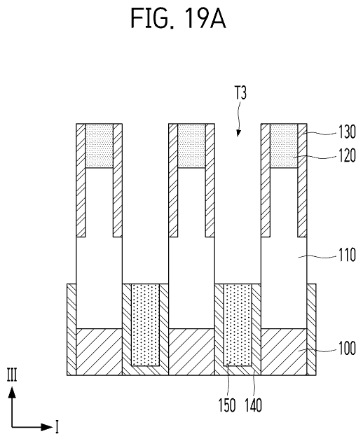

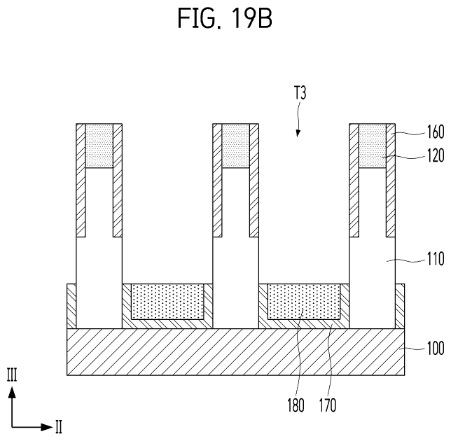

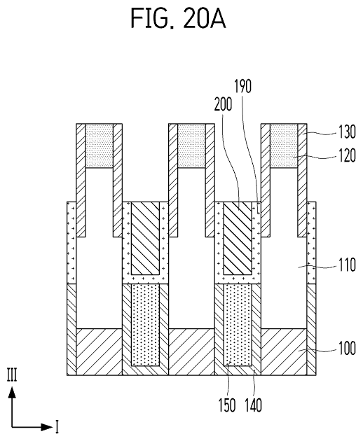

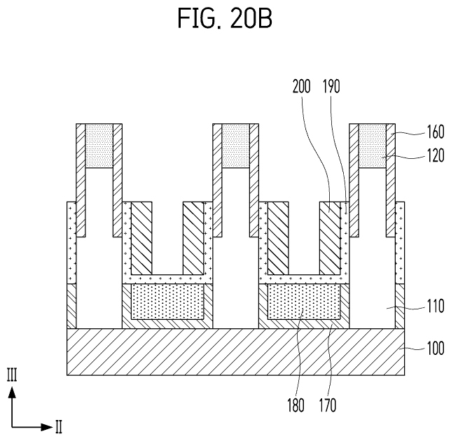

For example, the select lines 46 may each surround sidewalls of a plurality of the channel pillars CP arranged in the first direction I, and may each extend in the first direction I. The third gate insulating layers GL43 may be disposed between the channel pillars CP and the select lines 46 so as to surround the channel portion CHP. For example, the third gate insulating layers GL43 may each surround the channel portions CHP of the plurality of the channel pillars CP arranged in the first direction I, and overlap with corresponding (e.g., contacting) ones of the fourth and fifth gate insulating layers GL44 and GL45. The select lines 46 may surround the sidewalls of the channel pillars CP arranged in the first direction I with the third to fifth gate insulating layers GL43 to GL45 interposed therebetween. For example, the select lines 46 may each surround sidewalls of the plurality of the channel pillars CP arranged in the first direction I with corresponding (e.g., contacting or adjacent) ones of the third, fourth, and fifth gate insulating layers GL43, GL44, and GL45 interposed therebetween.

[symbol] he third gap-fill insulating layer GF43 may be disposed between the channel pillars CP adjacent to each other in the first direction I and between the channel pillars CP adjacent to each other in the second direction II so as to surround the first end portion E1. For example, the third gap-fill insulating layer GF43 may be disposed between a first pair of the channel pillars CP adjacent to each other in the first direction I and between a second pair of the channel pillars CP adjacent to each other in the second direction II so as to surround the first end portion E1 of a corresponding (e.g., adjacent) one of the channel pillars CP. The third gap-fill insulating layer GF43 may extend between the select lines (e.g., a pair of the select lines) 46 adjacent to each other in the second direction II.

[symbol] he local lines (e.g., local bit lines) 47 may be connected to the channel pillars CP, respectively. The local line 47 may be connected to the first end portion E1 of the channel pillar CP, and the global line 40 may be connected to the second end portion E2 of the channel pillar CP. The insulating layer 48 may be filled between the local lines 47.

[symbol] ccording to the structure described above, by overlapping the fourth and fifth gate insulating layers GL44 and GL45 with the third gate insulating layer GL43, it is possible to locally increase a thickness of a gate insulating layer. Accordingly, the occurrence of GIDL during an operation of a select transistor ST may be reduced.

[symbol] IGS. 5A and 5B are diagrams illustrating the structure of a semiconductor device in accordance with an embodiment. Hereinafter, the content overlapping with the previously described content may be omitted for the interest of brevity.

[symbol] eferring to FIGS. 5A and 5B, the semiconductor device may include channel pillars CP, first gate insulating layers GL51, second gate insulating layers GL52, third gate insulating layers GL53, first gap-fill insulating layers GF51, second gap-fill insulating layers GF52, and select lines 56. The semiconductor device may further include a third gap-fill insulating layer GF53, global lines 50, local lines 57, and an insulating layer 58.

[symbol] he channel pillars CP may be arranged in the first direction I and the second direction II intersecting the first direction I. Each of the channel pillars CP may include a first end portion E1, a second end portion E2, and a channel portion CHP. The global lines 50 may be disposed under the channel pillars CP. The global lines 50 may extend in the second direction II, and may each be connected to a plurality of the channel pillars CP arranged in the second direction II.

[symbol] he first gap-fill insulating layers GF51 may be disposed between the channel pillars CP adjacent to each other in the first direction I and between the global lines 50 adjacent to each other in the first direction I. The first gate insulating layers GL51 may be disposed between the channel pillars CP and the first gap-fill insulating layers GF51 so as to cover the second end portion E2. Upper surfaces of the first gap-fill insulating layers GF51 may be disposed at a lower level than upper surfaces of the first gate insulating layers GL51.

[symbol] he second gap-fill insulating layers GF52 may be disposed between the channel pillars CP adjacent to each other in the second direction II, and may extend in the first direction I. The second gate insulating layers GL52 may be disposed between the channel pillars CP and the second gap-fill insulating layers GF52 so as to cover the second end portion E2. Upper surfaces of the second gap-fill insulating layers GF52 may be disposed at a lower level than upper surfaces of the second gate insulating layers GL52.

[symbol] he select lines 56 may surround sidewalls of the channel pillars CP arranged in the first direction I, and may extend in the first direction I. The third gate insulating layers GL53 may be disposed between the channel pillars CP and the select lines 56 so as to surround the channel portion CHP. The select lines 56 may surround the sidewalls of the channel pillars CP arranged in the first direction I with the first to third gate insulating layers GL51 to GL53 interposed therebetween.

[symbol] he third gap-fill insulating layer GF53 may be disposed between the channel pillars CP adjacent to each other in the first direction I and between the channel pillars CP adjacent to each other in the second direction II so as to surround the first end portion E1. The third gap-fill insulating layer GF53 may extend between the select lines (e.g., a pair of the select lines) 56 adjacent to each other in the second direction II.

[symbol] he local lines (e.g., local bit lines) 57 may be connected to the channel pillars CP, respectively. The local line 57 may be connected to the first end portion E1 of the channel pillar CP, and the global line 50 may be connected to the second end portion E2 of the channel pillar CP. The insulating layer 58 may be filled between the local lines 57.

[symbol] ccording to the structure described above, by overlapping the first and second gate insulating layers GL51 and GL52 with the third gate insulating layer GL53, it is possible to locally increase a thickness of a gate insulating layer. Accordingly, the occurrence of GIDL during an operation of a select transistor ST may be reduced.

[symbol] IG. 6 is a diagram illustrating the structure of a semiconductor device in accordance with an embodiment. Hereinafter, the content overlapping with the previously described content may be omitted for the interest of brevity.

[symbol] eferring to FIG. 6, the semiconductor device may include global bit lines GBBL, select lines SL, local bit lines LBL, a stack STK, memory cells MC, and an interlayer insulating layer IL.

[symbol] he select lines SL may be disposed on the global bit lines GBBL, and select transistors ST may be disposed in regions where the global bit lines GBBL and the select lines SL intersect each other.

[symbol] he stack STK may be disposed on the interlayer insulating layer IL. The stack STK may include word lines WL and insulating layers 62 that are alternately stacked. The local bit lines LBL may extend in the third direction III through the stack STK. The memory cells MC may be disposed in regions where the local bit lines LBL and the word lines 61 intersect each other. The memory cells MC may be stacked along the local bit line LBL, and the memory cells MC stacked along the same local bit line LBL may constitute a memory unit MU.

[symbol] ach of the memory cells MC may include a first electrode 63, a variable resistance layer 64, and a second electrode 65. The second electrode 65 may surround a sidewall of the local bit line LBL. The variable resistance layer 64 may be disposed between the local bit line LBL and the word line WL. The first electrode 63 may be disposed between the variable resistance layer 64 and the word line WL.

[symbol] he variable resistance layer 64 may have characteristics that it reversibly transitions between different resistance states depending on a voltage or a current applied to the memory cell MC. As an example, when the variable resistance layer 64 has a low resistance state, data ‘1’ may be stored, and when the variable resistance layer 64 has a high resistance state, data ‘0’ may be stored.

[symbol] s an example, the variable resistance layer 64 may include a resistive material. An electrical path is generated or disappears in the variable resistance layer 64, such that data may be stored. As an example, the variable resistance layer 64 may include transition metal oxide or include metal oxide such as a perovskite-based material.

[symbol] s an example, the variable resistance layer 64 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

[symbol] s an example, the variable resistance layer 64 may include a phase change material or include a chalcogenide-based material. The variable resistance layer 64 may change its phase according to a program operation. As an example, the variable resistance layer 64 may have a low resistance crystalline state through a set operation. As an example, the variable resistance layer 64 may have a high resistance amorphous state through a reset operation. Accordingly, the data may be stored in the memory cell MC using a difference in resistance according to the phase of the variable resistance layer 64.

[symbol] s an example, the variable resistance layer 64 may include a variable resistance material whose resistance changes without a phase change or include a chalcogenide-based material. The variable resistance layer 64 may maintain its phase after the program operation. As an example, the variable resistance layer 64 may have an amorphous state, and may maintain the amorphous state without changing to a crystalline state after the program operation. A threshold voltage of the memory cell MC may be changed depending on a program voltage applied to the memory cell MC, and the memory cell MC may be programmed to at least two states. As an example, the memory cell MC may be programmed to a set state or a reset state using program voltages having different polarities. Accordingly, the data may be stored in the memory cell MC using a difference in the threshold voltage of the memory cell MC.

[symbol] ccording to the structure described above, the select transistors ST may be connected between the global bit lines GBBL and the local bit lines LBL, and the memory unit MU may be selected using the select transistors ST.

[symbol] IGS. 7A, 8A, 9A, 10A, 11A, and 12A, FIGS. 7B, 8B, 9B, 10B, 11B, and 12B, and FIGS. 7C, 8C, 9C, 10C, 11C, and 12C are diagrams for describing a method of manufacturing a semiconductor device in accordance with an embodiment. FIGS. 7A, 8A, 9A, 10A, 11A, and 12A are plan views, FIGS. 7B, 8B, 9B, 10B, 11B, and 12B are cross-sectional views taken along lines C-C′ of FIGS. 7A, 8A, 9A, 10A, 11A, and 12A, respectively, and FIGS. 7C, 8C, 9C, 10C, 11C, and 12C are cross-sectional views taken along lines D-D′ of FIGS. 7A, 8A, 9A, 10A, 11A, and 12A, respectively. Hereinafter, the content overlapping with the previously described content may be omitted for the interest of brevity.

[symbol] eferring to FIGS. 7A to 7C, a channel layer is formed on a conductive layer, and a hard mask 72 is formed on the channel layer. Subsequently, channel patterns 71 and global lines 70 may be formed by etching the channel layer and the conductive layer using the hard mask 72 as an etching barrier. The channel patterns 71 and global lines 70 may extend in the second direction II. First trenches T1 may be formed between the channel patterns 71 and between the global lines 70. For example, the first trenches T1 each may be formed between a pair of the channel patterns 71 adjacent in a first direction I intersecting the second direction II. The first trenches T1 may extend in the second direction II.

[symbol] ubsequently, a first gate insulating layer (or an initial first gate insulating layer) 73 may be formed in the first trenches T1. The first gate insulating layer 73 may be formed along profiles of the global lines 70, the channel patterns 71, and the hard mask 72. Subsequently, first gap-fill insulating layers 74 may be formed on the first gate insulating layer 73. The first gap-fill insulating layers 74 may be formed to fill the first trenches T1.

[symbol] eferring to FIGS. 8A to 8C, second trenches T2 extending in the first direction I may be formed by etching the channel patterns 71, the first gap-fill insulating layers 74, and the first gate insulating layer 73. For example, the channel pillars 71A, the second trenches T2, and intermediate first gate insulating layers 73A may be formed by etching the channel patterns 71, the first gap-fill insulating layers 74, and the initial first gate insulating layer 73. The channel patterns 71 may be separated into channel pillars 71A by the second trenches T2. The channel pillars 71A may be arranged in the first direction I and the second direction II. The channel pillars 71A may be spaced apart from each other by a second distance D2 in the second direction II, and may be spaced apart from each other by a first distance D1 smaller than the second distance D2 in the first direction I. First gap-fill insulating layers 74A and the intermediate first gate insulating layers 73A may be separated by the second trenches T2.

[symbol] ubsequently, a second gate insulating layer (or an initial second gate insulating layer) 75 may be formed in the second trenches T2. The second gate insulating layer 75 may be formed along surfaces of the channel pillars 71A, the global line 70, and the hard mask 72. Subsequently, second gap-fill insulating layers 76 may be formed on the second gate insulating layer 75. The second gap-fill insulating layers 76 may fill the second trenches T2.

[symbol] eferring to FIGS. 9A to 9C, a third trench T3 may be formed by etching the second gap-fill insulating layers 76, the second gate insulating layer 75, the first gap-fill insulating layers 74A, and the first gate insulating layer 73A. For example, the third trench T3, first gate insulating layers 73B, and second gate insulating layers 75A may be formed by etching the second gap-fill insulating layers 76, the initial second gate insulating layer 75, the first gap-fill insulating layers 74A, and the intermediate first gate insulating layers 73A. Sidewalls of the channel pillars 71A may be exposed through the third trench T3. Upper surfaces of first gap-fill insulating layers 74B and upper surfaces of first gate insulating layers 73B may be disposed at substantially the same level. Upper surfaces of second gap-fill insulating layers 76A and upper surfaces of second gate insulating layers 75A may be disposed at substantially the same level.

[symbol] eferring to FIGS. 10A to 10C, the first gap-fill insulating layers 74B and the second gap-fill insulating layers 76A may be selectively etched. Through this, upper surfaces of first gap-fill insulating layers (or etched first gap-fill insulating layers) 74C may be disposed at a lower level than the upper surfaces of the first gate insulating layers 73B. Upper surfaces of second gap-fill insulating layers (or etched second gap-fill insulating layers) 76B may be disposed lower than the upper surfaces of the second gate insulating layers 75A.

[symbol] eferring to FIGS. 11A to 11C, a third gate insulating layer (or an initial third gate insulating layer) 77 may be formed in the third trench T3. The third gate insulating layer 77 may be formed along profiles of the channel pillars 71A, the first gate insulating layers 73B, the first gap-fill insulating layers 74C, the second gate insulating layers 75A, the second gap-fill insulating layers 76B, and the hard mask 72. For example, the initial third gate insulating layer 77 may extend along surfaces of the first gate insulating layers 73B, the etched first gap-fill insulating layers 74C, the second gate insulating layers 75A, and the etched second gap-fill insulating layers 76B. The third gate insulating layer 77 may surround the sidewalls of the channel pillars 71A, and may overlap with the first and second gate insulating layers 73B and 75A.

[symbol] ubsequently, a conductive layer 78 may be formed on the third gate insulating layer 77. The conductive layer 78 may fill a portion of the third trench T3. The third trench T3 may have a first width W1 between the channel pillars 71A adjacent to each other in the first direction I. The third trench T3 may have a second width W2 greater than the first width W1 between the channel pillars 71A adjacent to each other in the second direction II. The conductive layer 78 may be deposited along a profile of the third gate insulating layer 77, and may substantially completely fill the third trench T3 between the channel pillars 71A adjacent to each other in the first direction I. However, the third trench T3 has a great width between the channel pillars 71A adjacent to each other in the second direction II, and may thus be partially filled with the conductive layer 78.

[symbol] eferring to FIGS. 12A to 12C, select lines 78A may be formed by etching the conductive layer 78. Third gate insulating layers 77A may be formed by etching the third gate insulating layer 77. The select lines 78A may surround sidewalls of the channel pillars 71A arranged in the first direction I, and may extend in the first direction I. The select lines 78A may surround the sidewalls of the channel pillars 71A with the first gate insulating layers 73B, the second gate insulating layers 75A, and the third gate insulating layers 77A interposed therebetween. For example, the select lines 78A may each surround a plurality of the channel pillars 71A arranged in the first direction I with corresponding ones of the first, second, and third gate insulating layers 73B, 75A, and 77A interposed therebetween.

[symbol] ubsequently, although not illustrated in FIGS. 12A to 12C, local lines (e.g., local bit lines) respectively connected to the channel pillars 71A and extending in the third direction III may be formed. The third direction III may intersect the first and section directions I and II. As an example, a stack including first material layers and second material layers that are alternately stacked may be formed on the channel pillars 71A. Subsequently, holes extending through the stack and respectively exposing the channel pillars 71A may be formed. Subsequently, grooves may be formed by etching the first material layers, and first electrode layers and variable resistance layers may be formed in the grooves. Subsequently, the local lines may be formed in the holes. The local lines may each have a pillar shape in which they fill the holes. Subsequently, the first material layers may be replaced with word lines.

[symbol] ccording to the method described above, the third gate insulating layer 77A may be formed to overlap with corresponding (e.g., contacting) ones of the first and second gate insulating layers 73B and 75A. Accordingly, it is possible to locally increase a thickness of a gate insulating layer of a select transistor.

[symbol] IGS. 13A, 14A, 15A, 16A, 17A, an 18A and FIGS. 13B, 14B, 15B, 16B, 17B, an 18B are diagrams for describing a method of manufacturing a semiconductor device in accordance with an embodiment. Hereinafter, the content overlapping with the previously described content may be omitted for the interest of brevity.

[symbol] eferring to FIGS. 13A and 13B, a channel layer 81 is formed on a conductive layer 80, and a hard mask 82 is formed on the channel layer 81. Subsequently, first preliminary trenches PT1 may be formed by etching the channel layer 81 using the hard mask 82 as an etching barrier. The first preliminary trenches PT1 may be formed by etching the channel layer 81 by a partial thickness. The first preliminary trenches PT1 may extend in the second direction II. Subsequently, a fourth gate insulating layer (or an initial fourth gate insulating layer) 83 may be formed in the first preliminary trenches PT1. The fourth gate insulating layer 83 may be formed along profiles of the channel layer 81 and the hard mask 82.

[symbol] eferring to FIGS. 14A and 14B, fourth gate insulating layers 83A and channel patterns 81A may be formed by etching the initial fourth gate insulating layer 83 and the channel layer 81. Subsequently, global lines 80A may be formed by etching the conductive layer 80. Through this, first trenches T1 may be formed.

[symbol] he channel patterns 81A, the global lines 80A, and the first trenches T1 may extend in the second direction II. The fourth gate insulating layers 83A may surround upper sidewalls of the channel patterns 81A. A lower portion of the channel pattern 81A may have a greater width than an upper portion of the channel pattern 81A, and a difference in width between the upper portion and the lower portion of the channel pattern 81A may correspond to thicknesses of the fourth gate insulating layers 83A.

[symbol] ubsequently, a first gate insulating layer (or an initial first gate insulating layer) 84 may be formed in the first trenches T1. The first gate insulating layer 84 may be formed along profiles of the global lines 80A, the channel patterns 81A, the fourth gate insulating layers 83A, and the hard mask 82. Subsequently, first gap-fill insulating layers 85 may be formed on the first gate insulating layer 84. The first gap-fill insulating layers 85 may be formed to fill the first trenches T1.

[symbol] eferring to FIGS. 15A and 15B, second preliminary trenches PT2 may be formed by etching the hard mask 82, the channel patterns 81A, the first gap-fill insulating layers 85, the initial first gate insulating layer 84, and the fourth gate insulating layers 83A. The second preliminary trenches PT2 may be formed by etching the channel patterns 81A by a partial thickness. The second preliminary trenches PT2 may extend in the first direction I. Subsequently, a fifth gate insulating layer (or an initial fifth gate insulating layer) 86 may be formed in the second preliminary trenches PT2. The fifth gate insulating layer 86 may be formed along profiles of the channel patterns 81A and the hard mask 82.

[symbol] eferring to FIGS. 16A and 16B, channel pillars 81B, fifth gate insulating layers 86A, and second trenches T2 may be formed by etching the channel patterns 81A, the initial fifth gate insulating layer 86, the first gate insulating layers 84, and the first gap-fill insulating layers 85. The channel pillars 81B may be arranged in the first direction I and the second direction II. The second trenches T2 may extend in the first direction I.

[symbol] he channel pillar 81B may have a rectangular plane, and may include first sidewalls facing each other in the first direction I and second sidewalls facing each other in the second direction II. The fourth gate insulating layers 83A may be formed on the first sidewalls of the channel pillar 81B, and fifth gate insulating layers 86A may be formed on the second sidewalls of the channel pillar 81B. A lower portion of the channel pillar 81B may have a greater width than an upper portion of the channel pillar 81B. A difference in width between the upper portion and the lower portion of the channel pillar 81B in the first direction I may correspond to thicknesses of the fourth gate insulating layers 83A, and a difference in width between the upper portion and the lower portion of the channel pillar 81B in the second direction II may correspond to thicknesses of the fifth gate insulating layers 86A.

[symbol] ubsequently, a second gate insulating layer 87 may be formed in the second trenches T2. The second gate insulating layer 87 may be formed along surfaces of the hard mask 82, the fifth gate insulating layers 86A, the channel pillars 81B, and the global lines 80A. Subsequently, second gap-fill insulating layers 88 may be formed on the second gate insulating layer 87. The second gap-fill insulating layers 88 may fill the second trenches T2.

[symbol] eferring to FIGS. 17A and 17B, a third trench T3 may be formed by etching the second gap-fill insulating layers 88, the second gate insulating layer 87, the first gap-fill insulating layers 85, and the first gate insulating layers 84. The fourth gate insulating layers 83A and the fifth gate insulating layers 86A may be exposed through the third trench T3. Sidewalls of the channel pillars 81B may be exposed through the third trench T3. The sidewalls of the channel pillars 81B may be exposed between first gate insulating layers 84A and the fourth gate insulating layers 83A and between second gate insulating layers 87A and the fifth gate insulating layers 86A.

[symbol] eights of upper surfaces of first gap-fill insulating layers 85A and upper surfaces of the first gate insulating layers 84A may be substantially the same as or different from each other. Heights of upper surfaces of second gap-fill insulating layers 88A and upper surfaces of the second gate insulating layers 87A may be substantially the same as or different from each other. As an example, the upper surfaces of the first gap-fill insulating layers 85A may be disposed at a lower level than the upper surfaces of the first gate insulating layers 84A. The upper surfaces of the second gap-fill insulating layers 88A may be disposed at a lower level than the upper surfaces of the second gate insulating layers 87A.

[symbol] eferring to FIGS. 18A and 18B, third gate insulating layers 89 and select lines 90 may be formed in the third trench T3. The third gate insulating layers 89 may overlap with the first gate insulating layers 84A, the second gate insulating layers 87A, the fourth gate insulating layers 83A, and the fifth gate insulating layers 86A. For example, each of the third gate insulating layers 89 may overlap with corresponding (e.g., contacting) ones of the fourth and fifth gate insulating layers 83A and 86A.

[symbol] ccording to the method described above, the third gate insulating layers 89 may be formed to overlap with the first, second, fourth, and fifth gate insulating layers 84A, 87A, 83A, and 86A. Accordingly, it is possible to locally increase a thickness of a gate insulating layer of a select transistor.

[symbol] IGS. 19A, 19B, 20A, and 20B are diagrams for describing a method of manufacturing a semiconductor device in accordance with an embodiment. Hereinafter, the content overlapping with the previously described content may be omitted for the interest of brevity.

[symbol] eferring to FIGS. 19A and 19B, global lines 100, channel pillars 110, a hard mask 120, a first gate insulating layer 140, first gap-fill insulating layers 150, a second gate insulating layer 170, second gap-fill insulating layers 180, fourth gate insulating layers 130, and fifth gate insulating layers 160 may be formed.

[symbol] ubsequently, a third trench T3 may be formed by etching the second gap-fill insulating layers 180, the second gate insulating layer 170, the first gap-fill insulating layers 150, and the first gate insulating layer 140. The fourth gate insulating layers 130 and the fifth gate insulating layers 160 may be exposed through the third trench T3. Sidewalls of the channel pillars 110 may be exposed through the third trench T3. The sidewalls of the channel pillars 110 may be exposed between the first gate insulating layers 140 and the fourth gate insulating layers 130 and between the second gate insulating layers 170 and the fifth gate insulating layers 160. Upper surfaces of the first gap-fill insulating layers 150 and upper surfaces of the first gate insulating layers 140 may be at substantially the same level as each other. Upper surfaces of the second gap-fill insulating layers 180 and upper surfaces of the second gate insulating layers 170 may be at substantially the same level as or different from each other.

[symbol] eferring to FIGS. 20A and 20B, third gate insulating layers 190 and select lines 200 may be formed in the third trench T3. The third gate insulating layers 190 may overlap with the fourth gate insulating layers 130 and the fifth gate insulating layers 160.

[symbol] ccording to the method described above, the third gate insulating layer 190 may be formed to overlap with the fourth and fifth gate insulating layers 130 and 160. Accordingly, it is possible to locally increase a thickness of a gate insulating layer of a select transistor.

[symbol] lthough some embodiments of the present disclosure have been described over with reference to the accompanying drawings, various embodiments of the present disclosure are not limited to the above-described embodiments. Various types of substitutions, modifications, changes, and combinations for the embodiments may be made by those skilled in the art, to which the present disclosure pertains, and these substitutions, modifications, changes, and combinations belong to embodiments of the present disclosure.

What is claimed is:

1. A semiconductor device comprising:
channel pillars arranged in a first direction and a second direction intersecting the first direction, each of the channel pillars including a first end portion, a second end portion, and a channel portion disposed between the first end portion and the second end portion;
first gap-fill insulating layers each disposed between a first pair of the channel pillars adjacent to each other in the first direction;
first gate insulating layers each disposed between a corresponding one of the channel pillars and a corresponding one of the first gap-fill insulating layers so as to cover the second end portion;
second gap-fill insulating layers each disposed between a second pair of the channel pillars adjacent to each other in the second direction and extending in the first direction;
second gate insulating layers each disposed between the corresponding one of the channel pillars and a corresponding one of the second gap-fill insulating layers so as to cover the second end portion;
select lines each surrounding sidewalls of a first plurality of the channel pillars arranged in the first direction and extending in the first direction; and
third gate insulating layers each surrounding the channel portions of the first plurality of the channel pillars and overlapping with corresponding ones of the first and second gate insulating layers.

2. The semiconductor device of claim 1, wherein each of the select lines surrounds the sidewalls of the first plurality of the channel pillars arranged in the first direction with the corresponding ones of the first, second, and third gate insulating layers interposed therebetween.

3. The semiconductor device of claim 1, wherein upper surfaces of the first gap-fill insulating layers are disposed at a lower level than upper surfaces of the first gate insulating layers, and
wherein upper surfaces of the second gap-fill insulating layers are disposed at a lower level than upper surfaces of the second gate insulating layers.

4. The semiconductor device of claim 3, wherein the third gate insulating layers extend along surfaces of the first gate insulating layers, the first gap-fill insulating layers, the second gate insulating layers, and the second gap-fill insulating layers.

5. The semiconductor device of claim 1, wherein each of the third gate insulating layers comprises:
a first portion surrounding the channel portion of a corresponding one of the channel pillars; and
a second portion covering a corresponding one of the first gate insulating layers and a corresponding one of the second gate insulating layers.

6. The semiconductor device of claim 5, wherein each of the select lines has a first portion that is covered by the first portion of a corresponding one of the third gate insulating layers and has a first width, and
wherein each of the select lines has a second portion that is covered by the second portion of the corresponding one of the third gate insulating layers and has a second width smaller than the first width.

7. The semiconductor device of claim 1, further comprising a third gap-fill insulating layer disposed between the first pair of the channel pillars adjacent to each other in the first direction and between the second pair of the channel pillars adjacent to each other in the second direction so as to surround the first end portion of the corresponding one of the channel pillars.

8. The semiconductor device of claim 7, wherein the third gap-fill insulating layer extends between a pair of the select lines adjacent to each other in the second direction.

9. The semiconductor device of claim 1, further comprising fourth gate insulating layers covering respective sidewalls of the first end portion that face each other in the first direction,
wherein the third gate insulating layers each overlap with a corresponding one of the fourth gate insulating layers.

10. The semiconductor device of claim 1, further comprising fifth gate insulating layers covering respective sidewalls of the first end portion that face each other in the second direction,
wherein the third gate insulating layers each overlap with a corresponding one of the fifth gate insulating layers.

11. The semiconductor device of claim 1, wherein the first pair of the channel pillars are spaced apart from each other by a first distance, and the second pair of the channel pillars arranged are spaced apart from each other by a second distance, the first distance being smaller than the second distance.

12. The semiconductor device of claim 1, further comprising:
word lines stacked over the channel pillars;
local bit lines extending through the word lines and connected to the channel pillars, respectively; and
global bit lines disposed under the channel pillars and each connected to a second plurality of the channel pillars arranged in the second direction.

13. A semiconductor device comprising:
channel pillars arranged in a first direction and a second direction intersecting the first direction, each of the channel pillars including a first end portion, a second end portion, and a channel portion disposed between the first end portion and the second end portion;
fourth gate insulating layers covering respective sidewalls of the first end portion that face each other in the first direction;
fifth gate insulating layers covering respective sidewalls of the first end portion that face each other in the second direction;
select lines each extending in the first direction and surrounding sidewalls of a first plurality of the channel pillars arranged in the first direction; and
third gate insulating layers each surrounding the channel portions of the first plurality of the channel pillars and overlapping with corresponding ones of the fourth and fifth gate insulating layers.

14. The semiconductor device of claim 13, further comprising:
first gap-fill insulating layers each disposed between a first pair of the channel pillars adjacent to each other in the first direction;
first insulating layers each disposed between a corresponding one of the channel pillars and a corresponding one of the first gap-fill insulating layers so as to cover the second end portion;
second gap-fill insulating layers each disposed between a second pair of the channel pillars adjacent to each other in the second direction and extending in the first direction; and
second gate insulating layers each disposed between the corresponding one of the channel pillars and a corresponding one of the second gap-fill insulating layers so as to cover the second end portion.

15. The semiconductor device of claim 14, wherein the third gate insulating layers each overlap with a corresponding one of the first gate insulating layers and a corresponding one of the second gate insulating layers.

16. The semiconductor device of claim 13, wherein each of the select lines surrounds the sidewalls of the first plurality of the channel pillars arranged in the first direction with the corresponding ones of the third, fourth, and fifth gate insulating layers interposed therebetween.

17. The semiconductor device of claim 13, wherein the first end portion has a first width and the second end portion has a second width, the first width being smaller than the second width.

18. The semiconductor device of claim 13, wherein a first pair of the channel pillars are spaced apart from each other by a first distance, and a second pair of the channel pillars arranged in the second direction are spaced apart from each other by a second distance, the first distance being smaller than the second distance.

19. The semiconductor device of claim 13, further comprising:
word lines stacked over the channel pillars;
local bit lines extending through the word lines and connected to the channel pillars, respectively; and
global bit lines disposed under the channel pillars and each connected to a second plurality of the channel pillars arranged in the second direction.
